(19) United States
(12) Patent Application Publication
(10) Pub. No.: US 2015/0048281 A1
(43) Pub. Date: Feb. 19, 2015

(54) OXIDE FILM AND PROCESS FOR PRODUCING SAME

(71) Applicant: Ryukoku University, Kyoto (JP)

(72) Inventors: Seiji Yamazoe, Kanagawa (JP); Takahiro Wada, Osaka (JP)

(73) Assignee: Ryukoku University, Kyoto (JP)

(21) Appl. No.: 14/387,219

(22) PCT Filed: Mar. 1, 2013
(86) PCT No.: PCT/JP2013/055646

§ 371 Date: Sep. 22, 2014

(30) Foreign Application Priority Data
Mar. 26, 2012 (JP) 2012-068695

(51) Int. Cl. C01G 53/00; C23C 14/28; C23C 14/34; H01B 1/08; C23C 14/08

(52) U.S. Cl. CPC C01G 53/42; H01B 1/08; C23C 14/08; C23C 14/34; C23C 14/28; C01P 2006/40
USPC 252/519.1; 423/594.3; 204/192.15; 427/596

(57) ABSTRACT

An oxide film according to this invention is a film of an oxide (possibly including inevitable impurities) containing silver (Ag) and nickel (Ni). This oxide film is an aggregate of microcrystals, an amorphous form including microcrystals, or an amorphous form and has p-type conductivity, which exhibits no clear diffraction peak with the XRD analysis, as seen in a chart in FIG. 3 indicating X-ray diffraction (XRD) analysis results of a first oxide film and a second oxide film. This oxide film achieves a broader bandgap than that of a conventional oxide film as well as high p-type conductivity. This oxide film is an aggregate of microcrystals, an amorphous form containing microcrystals, or an amorphous form as described above, and is thus easily formed on a large substrate and is suitable also for industrial production.

### TECHNICAL FIELD

The present invention relates to an oxide film and a process for producing the same.

### BACKGROUND ART

Various oxide films having transparency or conductivity have been researched conventionally. A film having both transparency and conductivity is particularly referred to as a transparent conductive film and is widely used as an important component material in a device such as a flat panel display or a solar battery.

Typical materials for transparent conductive films that have been so far employed are indium tin oxide (ITO) and zinc oxide (ZnO). Indium tin oxide (ITO) is known particularly for high transparency and conductivity, is also stable as a material, and has thus been used in various types of devices for many years. ITO shows, however, only n-type conductivity, and has thus a limited range of application. Meanwhile, as zinc oxide (ZnO) that has recently received attention as a subject of research and development for performance improvement, not only pure zinc oxide but also zinc oxide, to which aluminum (Al) and chromium (Cr) are added, and the like, have been developed (see Patent Document 1). Zinc oxide originally has, however, low stability to moisture or heat as compared with ITO, and is thus difficult to be handled.

Transparent conductive films showing n-type conductivity have a large number of types such as ZnO doped with Al and SnO₂ doped with fluorine as well as ITO mentioned above. It can be said, however, that research and development for performance improvement of transparent conductive films having p-type conductivity are yet halfway through. Exemplarily disclosed is that a film of CuAlO₂, a complex oxide of copper (Cu) and aluminum (Al), and a film of SrCu₂O₂, a complex oxide of copper (Cu) and strontium (Sr), show p-type conductivity (see Non-Patent Document 1). They have, however, very low conductances. Patent Documents 2 and 3 shown below disclose that an oxide, to which several elements are added, has properties as a transparent conductive film. None of these documents, however, includes specific disclosure concerning conductivity and a visible light transmittance for all the elements disclosed therein, and is thus difficult to be employed as a technical document on transparent conductive films.

The inventors of the present application have proposed an oxide film (see Patent Document 4) as a solution to the technical problems mentioned above. The oxide film has a relatively narrow bandgap of 2.6 eV, so that there are demands for a high-performance transparent conductive film.

### PRIOR ART DOCUMENTS

### Patent Documents

Patent Document 1: JP 2002-75061 A
Patent Document 2: JP 2007-142028 A
Patent Document 3: JP 2008-507842 A
Patent Document 4: JP 2011-174167 A

### Non-Patent Document

Non-Patent Document 1: Jaroslaw Domaradzki and three other persons, “Transparent oxide semiconductors based on TiO2 doped with V, Co and Pd elements”, Journal of Non-Crystalline Solids, 2006, vol. 352, pp. 2324-2327.

### SUMMARY OF THE INVENTION

### Problems to be Solved by the Invention

As described above, performance improvement of oxide films as conductive films, particularly transparent conductive films, which show p-type conductivity, is far behind that of n-type conductive films. Specifically, the p-type transparent conductive films currently developed mainly have the problem of low transparency or conductivity. The oxide film devised by the inventors of the present application is much more excellent than a former oxide film. Performance improvement of oxide films as transparent conductive films are yet halfway through.

Crystalline oxide films may have the problem of orientation control on crystals, which determines physical properties of the films. In this sense, employment of a crystalline oxide film that does not adequately exhibit its performance unless it does not have specific crystal orientation may pose a technical barrier for mass production or increase in size of substrates when industrialization is taken into consideration.

### Solutions to the Problems

The present invention solves at least one of the technical problems mentioned above and thus contributes largely to further performance improvement of an oxide film as a p-type conductive film, particularly a p-type transparent conductive film. Considering that performance improvement of an oxide film having p-type conductivity would be absolutely necessary for expansion in range of application of conductive films, the inventors tried to employ not only elements that had been studied for many years but also new elements that had not been studied seriously for improvement in conductivity or transparency of the oxide film. The inventors have gone through many trials and errors while considering also an oxide film having a bandgap exceeding the bandgap of the oxide film having been devised by the inventors as a p-type transparent conductive film. The inventors found that an oxide containing specific elements achieves a high conductance and a high transmittance while having quite a broad bandgap. The inventors repeated studies and also found that the material requires relatively less strict production conditions for achieving desired properties, so that the degree of freedom in production may be extremely increased. The present invention has been devised through such findings and circumstances.

An oxide film according to the present invention is a film of an oxide (possibly including inevitable impurities) containing silver (Ag) and nickel (Ni), wherein the oxide film is an aggregate of microcrystals, an amorphous form including microcrystals, or anamorphous form, and has p-type conductivity.

This oxide film achieves a high p-type conductivity while having quite a broader bandgap than that of a conventional oxide film. This oxide in a film shape forms an aggregate of microcrystals, an amorphous form including microcrystals, or an amorphous form, and exhibits high p-type conductivity. This oxide film is an aggregate of microcrystals, an amorphous form including microcrystals, or anamorphous form, and is thus easily formed on a large substrate and is suitable also for industrial production.

Another oxide film according to the present invention is a film of an oxide (possibly including inevitable impurities) containing silver (Ag) and nickel (Ni), wherein the ratio of the number of the silver (Ag) atoms to the number of the nickel (Ni) atoms assumed to be 1 is 0.01 or more and 0.1 or less, and the oxide film is an aggregate of microcrystals, an amorphous form including microcrystals, or an amorphous form, and has p-type conductivity.

This oxide film achieves a high p-type conductivity while having quite a broader bandgap than that of a conventional oxide film. This oxide in a film shape forms an aggregate of microcrystals, an amorphous form including microcrystals, or an amorphous form, and exhibits high p-type conductivity. An oxide film having high transparency is obtained by employing the specific elements described above and satisfying the ratio of the number of atoms in the specific range described above. Furthermore, this oxide film is an aggregate of microcrystals, an amorphous form including microcrystals, or an amorphous form, and is thus easily formed on a large substrate and is suitable also for industrial production.

A process for producing an oxide film according to the present invention includes the step of scattering constituent atoms of a target of an oxide containing silver (Ag) and nickel (Ni) to form on a substrate a first oxide film (possibly including inevitable impurities) which is an aggregate of microcrystals, an amorphous form including microcrystals, or an amorphous form and has p-type conductivity.

This process for producing the oxide film achieves an oxide film that has a broader bandgap than that of a conventional oxide film as well as high p-type conductivity. This oxide in a film shape forms an aggregate of microcrystals, an amorphous form including microcrystals, or an amorphous form, and exhibits high p-type conductivity. Furthermore, according to this method for producing the oxide film, the oxide film thus obtained is an aggregate of microcrystals, an amorphous form including microcrystals, or an amorphous form, and can be thus easily formed on a large substrate and is suitable also for industrial production.

A process for producing an oxide film according to the present invention includes the step of scattering constituent atoms of a target of an oxide containing silver (Ag) and nickel (Ni) to form on a substrate a first oxide film (possibly including inevitable impurities), wherein the ratio of the number of the silver (Ag) atoms to the number of the nickel (Ni) atoms assumed to be 1 is 0.01 or more and 0.1 or less, and the oxide film is an aggregate of microcrystals, an amorphous form including microcrystals, or an amorphous form and has p-type conductivity.

This process for producing the oxide film achieves an oxide film that has a high p-type conductivity while having quite a broader bandgap than that of a conventional oxide film. This oxide in a film shape forms an aggregate of microcrystals, an amorphous form including microcrystals, or an amorphous form, and exhibits high p-type conductivity. The transparency of the oxide film is significantly improved by employing the specific elements described above and satisfying the ratio of the number of atoms in the specific range described above. Furthermore, according to this method for producing the oxide film, the oxide film thus obtained is an aggregate of microcrystals, an amorphous form including microcrystals, or an amorphous form, and can be thus easily formed on a large substrate and is suitable also for industrial production.

A “substrate” in the present application means typically a glass substrate, a semiconductor substrate, a metal substrate, or a plastic substrate, but is not limited thereto. The “substrate” in the present application is not limited to a flat structure but can also have a curved structure. Furthermore, a “temperature of a substrate” in the present application means a set temperature of a heater for heating a stand or an appliance for supporting, holding, or accommodating the substrate unless otherwise specified. An “oxide” and an “oxide film” in the present application may contain impurities that cannot be prevented from being mixed therein upon production. Typical examples of these impurities include impurities that can be mixed during production of a target, impurities contained in various types of substrates, and impurities contained in water used in the steps of producing various types of devices. Accordingly, it cannot be said that the impurities can always be detected by most advanced analytical instruments at the stage when the present application was filed, typical examples of such impurities include aluminum (Al), silicon (Si), iron (Fe), sodium (Na), calcium (Ca), and magnesium (Mg).

### Effects of the Invention

An oxide film according to the present invention achieves a high p-type conductivity while having quite a broader bandgap than that of a conventional oxide film. Furthermore, this oxide film does not need to be limited to a specific crystal structure and is thus easily formed on a large substrate and is suitable also for industrial production.

A process for producing an oxide film according to the present invention achieves an oxide film that has a high p-type conductivity while having quite a broader bandgap than that of a conventional oxide film. This oxide in a film shape forms an aggregate of microcrystals, an amorphous form including microcrystals, or an amorphous form, and exhibits high p-type conductivity. Furthermore, according to this method for producing the oxide film, the oxide film thus obtained is an aggregate of microcrystals, an amorphous form including microcrystals, or an amorphous form, and can be thus easily formed on a large substrate and is suitable also for industrial production.

### BRIEF DESCRIPTION OF THE DRAWINGS

FIG. 1 is an explanatory view of a production apparatus for a first oxide film in a first embodiment of the present invention.

FIG. 2A is an explanatory view showing one of the steps of forming a second oxide film in the first embodiment of the present invention.

FIG. 2B is an explanatory view showing one of the steps of forming the second oxide film in the first embodiment of the present invention.

FIG. 3 is a chart indicating X-ray diffraction (XRD) analysis results of the first oxide film in the first embodiment of the present invention.

FIG. 4 is a chart showing the result of analysis of the transmittance of the first oxide film in the first embodiment of the present invention to a light ray having a wavelength principally in a visible light region.

FIG. 5 is a chart indicating X-ray diffraction (XRD) analysis results of the second oxide film in the first embodiment of the present invention.

FIG. 6 is a chart showing the result of analysis of the transmittance of the second oxide film in the first embodiment of the present invention to a light ray having a wavelength principally in a visible light region.

FIG. 7 is a chart indicating X-ray diffraction (XRD) analysis results of a first oxide film in a second embodiment of the present invention.

FIG. 8 is a chart showing the result of analysis of the transmittance of the first oxide film in the second embodiment of the present invention to a light ray having a wavelength principally in a visible light region.

FIG. 9 is a chart indicating X-ray diffraction (XRD) analysis results of a first oxide film in a third embodiment of the present invention.

FIG. 10 is a chart showing the result of analysis of the transmittance of the first oxide film in the third embodiment of the present invention to a light ray having a wavelength principally in a visible light region.

### DESCRIPTION OF REFERENCE SIGNS

10 Substrate
11 First oxide film
12 Second oxide film
20 Pulse laser deposition apparatus
21 Chamber
22 Excimer laser
23 Lens
24 Holder
25a Oxygen gas cylinder
25b Nitrogen gas cylinder
26 Inlet
27 Stage
28 Evacuation port
29 Vacuum pump
30 Target

### EMBODIMENTS OF THE INVENTION

Embodiments of the present invention will be described in detail with reference to the accompanying drawings. It is to be noted that, in this description, common parts are denoted by common reference signs unless otherwise specified throughout the drawings. In these drawings, each of components according to the embodiments is not necessarily illustrated with a mutual scale ratio maintained. Some reference signs may not appear for the sake of clarity in the drawings.

### First Embodiment

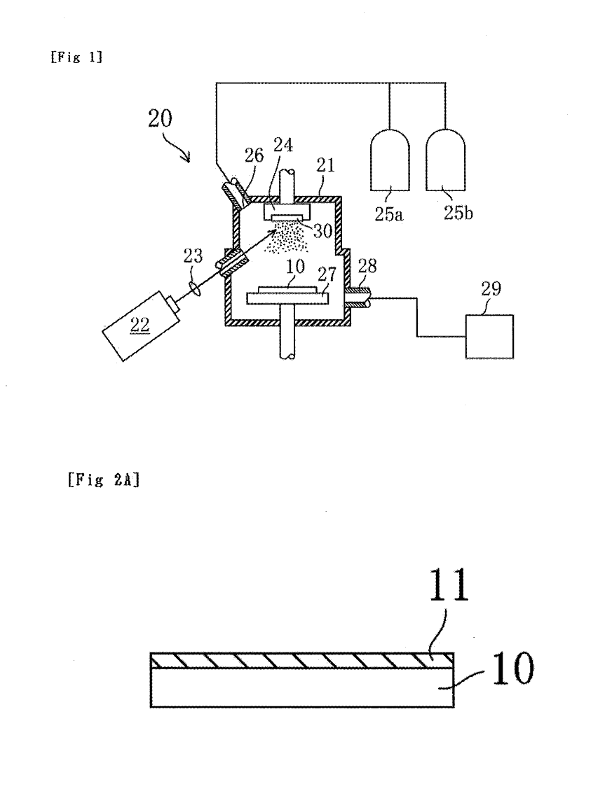

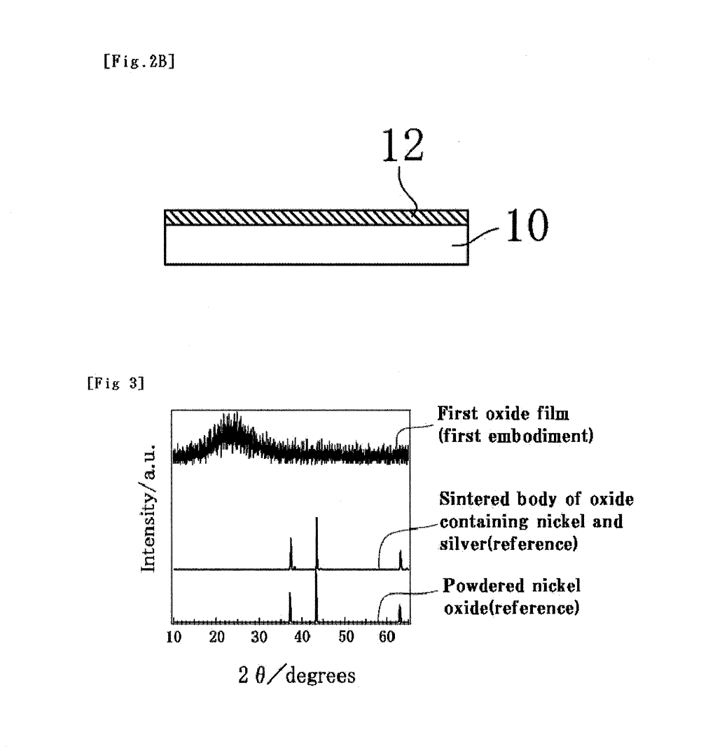

An oxide film containing silver (Ag) and nickel (Ni) and a process for producing the same will be described in this embodiment. FIG. 1 is an explanatory view of a production apparatus for a first oxide film in this embodiment. FIGS. 2A and 2B are explanatory views each showing one of the steps of forming a second oxide film in this embodiment.

Prior to production of an oxide film as a final object, an oxide sintered body as a raw material for the oxide film was produced in this embodiment. Initially, nickel oxide (NiO) and silver nitrate (AgNO₃) were physically mixed. In this embodiment, these compounds were mixed using a known grinding mixer (manufactured by Ishikawa Kojo; Model AGA; the same applies hereinafter). These two compounds were mixed so that the stoichiometric ratio of Ni and Ag was substantially 1:0.05. The nickel oxide (NiO) used in this embodiment was manufactured by Kojundo Chemical Lab. Co., Ltd. and has a nominal purity of 99.97%. The silver nitrate (AgNO₃) used in this embodiment was manufactured by Kojundo Chemical Lab. Co., Ltd. and has a nominal purity of 99%.

A molded product of the oxide was then obtained in this embodiment by compression-molding a powdered mixture of the oxide using a commercially available tablet molding machine (manufactured by NPA SYSTEM CO., LTD.; Model TB-5H). Pressure applied at this time was about 68.4 MPa. The baking step was carried out for five hours using a commercially available muffle furnace (manufactured by Motoyama; Model MS-2520) heated to 1100° C. with the molded product placed on the powdered mixture mounted on an alumina plate.

A sintered body of an oxide (hereinafter, also referred to simply as an oxide sintered body) containing silver (Ag) and nickel (Ni) obtained through the baking step had a relative density of about 90%. The crystal structure of this oxide sintered body was measured and analyzed using an X-ray diffraction (XRD) analyzer (manufactured by Rigaku Corporation; product name “Automatic X-Ray Diffractometer RINT (registered trademark) 2000”). Nickel oxide (NiO) and silver (Ag) were found to have no solid solution relationship but coexist in the oxide sintered body. A θ/2θ method was employed in this XRD measurement. The voltage in X-ray irradiation was 40 kV and the tube current was 100 mA. A target of an X-ray generating part was copper. All of the following XRD analyses were carried out using the XRD analyzer mentioned above.

As shown in FIG. 1, an oxide film was then produced on a substrate 10 using a pulse laser deposition apparatus 20. A laser source of the pulse laser deposition apparatus 20 was of Model Compex 201 and manufactured by Lambda Physik AG, and its chamber was a pulse laser deposition apparatus manufactured by Neocera Inc. The substrate 10 according to this embodiment is a borosilicate glass substrate. The oxide sintered body described above was employed as a target 30. The substrate 10 was attached to be placed via liquid indium onto a stage (or a substrate holder; hereinafter uniformly referred to as a stage) 27 within a chamber 21 exposed to the atmosphere, and air within the chamber 21 was then evacuated through an evacuation port 28 using a known vacuum pump 29. Air was evacuated until pressure within the chamber 21 reached the order of 10⁻⁴ Pa, and the temperature of a heater (not shown) within the stage 27 was then set to 500° C. The temperature of the heater was set to 500° C. in this embodiment, although the temperature of the heater is not limited thereto in this embodiment. For example, a temperature of the heater set to 0° C. or more and 500° C. or less can achieve at least a part of the effects of the oxide film according to this embodiment.

Oxygen (O₂) and nitrogen (N₂) were then fed into the chamber 21 from an oxygen gas cylinder 25a and a nitrogen gas cylinder 25b through an inlet 26. In the step of depositing an oxide film in this embodiment, evacuation by the vacuum pump 29 was adjusted so that the equilibrium pressure of gas (i.e. entire introduced gas) within the chamber 21 was 0.013 Pa. Introduced in this embodiment was mixed gas of oxygen and nitrogen such that the ratio of pressure of the oxygen to that of nitrogen was 1:4, but this embodiment is not limited to this mixed gas. For example, in place of nitrogen (N₂) gas, inert gas such as helium (He) gas or argon (Ar) gas may be introduced along with oxygen gas. Still alternatively, oxygen gas alone may be introduced. The equilibrium pressure of the gas within the chamber 21 in this embodiment was 0.013 Pa. Even when the equilibrium pressure is set to a different value (e.g. 0.01 Pa or more and 100 Pa or less), an oxide film similar to that according to this embodiment can be formed.

Thereafter, pulse krypton fluoride (KrF) excimer laser (wavelength 248 nm) 22 was collected by a lens 23 and was then emitted toward the target 30 held by a holder 24. By scattering the constituent atoms of the target 30 including the oxide sintered body by the excimer laser irradiation, a first oxide film 11 was formed on the substrate 10 as shown in FIG. 2A. The oscillatory frequency of the excimer laser in this embodiment was 10 Hz, the energy per unit area of a unit pulse was 200 mJ per pulse, and the number of times of irradiation was 100,000.

After the formation of the first oxide film 11, the substrate 10 was taken out of the chamber 21 exposed to the atmosphere. In this embodiment, the inventors heat-treated (annealed) the first oxide film 11 to form a second oxide film 12, in addition to the first oxide film 11. Specifically, indium adhering to the back surface of the substrate 10 was removed by hydrochloric acid, and the first oxide film 11 on the substrate 10 was then heat-treated under a condition of 200° C. or 400° C. for two hours within a chamber having the atmosphere with air fed thereinto. The second oxide film 12 was thus formed on the substrate 10 as shown in FIG. 2B.

The inventors measured the thickness of the second oxide film 12 using a multi-channel spectrometer (manufactured by Hamamatsu Photonics K.K.; product name “Multi-Channel Spectrometer PMA-12”) to find that the thickness was about 100 nm. Each of the following thickness measurement was made using the multi-channel spectrometer mentioned above and a scanning electron microscope (VE-9800) manufactured by KEYENCE CORPORATION.

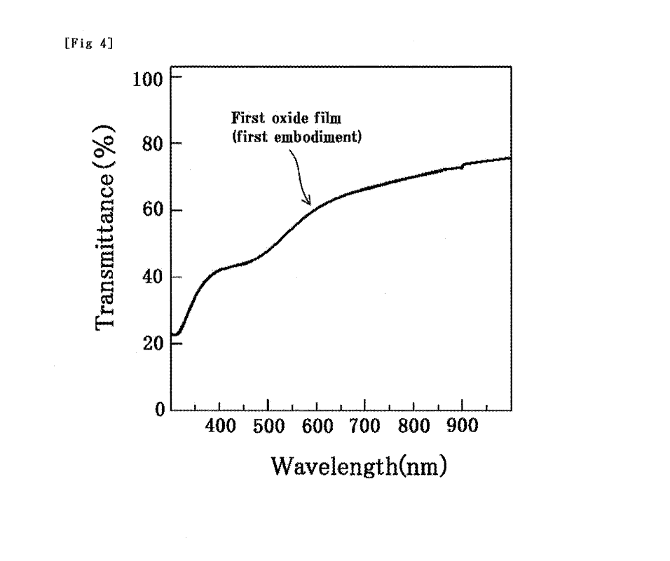

The inventors analyzed the crystal conditions of the first oxide film 11 by X-ray diffraction (XRD). FIG. 3 is a chart indicating X-ray diffraction (XRD) analysis results of the first oxide film 11 in this embodiment. FIG. 3 also indicates XRD analysis results of a sintered body of an oxide containing silver (Ag) and nickel (Ni) and powdered nickel oxide as reference data. Found by this analysis was a broad halo peak considered to result from an amorphous phase at 2θ in the range from 20° to 30° as indicated in FIG. 3. In other words, no clear peak resulting from the sintered body of the oxide or the nickel oxide was observed.

In view of the XRD analysis results of no clear diffraction peak as described above, the first oxide film 11 according to this embodiment is considered to be an aggregate of microcrystals, an amorphous form including microcrystals, or an amorphous form. According to observation by the inventors using the scanning electron microscope, the first oxide film 11 is considered to have a very flat surface.

Differently from this embodiment, according to the XRD analysis of a first oxide film 11 obtained through the step similar to that of this embodiment when the oxide sintered body is formed by mixing nickel oxide (NiO) and silver nitrate (AgNO₃) at the ratio of the number of Ag atoms to the number of Ni atoms assumed to be 1 is 0.01 or more and 0.1 or less, a relatively weak peak at around 37° considered to result from an (111) surface as orientation of a crystal surface is found in addition to the broad halo peak. Also from this result, the first oxide film 11 according to this embodiment is considered to be an aggregate of microcrystals, an amorphous form including microcrystals, or an amorphous form. It is interestingly observed that the peak at around 37° becomes smaller as the ratio of Ag mixed with Ni is increased.

The inventors analyzed electrical properties and a conductance of the first oxide film 11 using a Hall effect measurement apparatus (manufactured by ECOPIA, INC.; product name “Hall Effect Measurement System HMS-3000 Ver. 3.5”). The first oxide film 11 according to this embodiment had p-type conductivity and a conductance as high as about 37 S/cm.

As described above, the first oxide films 11 each had a conductance of a high value. The first oxide film not heat-treated, in other words, the first oxide film itself, interestingly achieves very high electrical properties and a very high conductance.

The inventors measured an absorption spectrum using an ultraviolet-visible infrared spectrophotometer (manufactured by JASCO Corporation; product name “V-670 ultraviolet-visible near infrared spectrophotometer”) to calculate a transmittance of the first oxide film 11 to a light ray having a wavelength of 400 nm or more and 750 nm or less (hereinafter, also referred to simply as a “visible light transmittance” or a “transmittance”). As a photo-detecting device, a photomultiplier tube was used in an ultraviolet-visible region and a cooling PbS photoconductive device was used in a near infrared region.

FIG. 4 is a chart indicating transmittance analysis results of the first oxide film 11 in this embodiment. As indicated in FIG. 4, the transmittance of the first oxide film 11 to a light ray having a wavelength of 400 nm or more and 750 nm or less was about 57%.

Differently from this embodiment, also analyzed was a transmittance of a first oxide film 11 obtained through the step similar to that of this embodiment when the oxide sintered body was formed by mixing nickel oxide (NiO) and silver nitrate (AgNO₃) at the ratio of the number of Ag atoms to the number of Ni atoms assumed to be 1 was 0.01 or more and 0.1 or less. The analysis results and the results of this embodiment were studied to find that a transmittance tended to increase as the ratio of Ag mixed with Ni is decreased. Particularly a transmittance will thus be high (e.g. 70% or more) when Ag is 0.01 or more and 0.02 or less relatively to Ni assumed to be 1.

As described above, interestingly, the first oxide film 11 immediately after being deposited was founded to have the excellent electrical properties, conductance, and transmittance through the analyses of the electrical properties, conductance, and transmittance. It is thus possible to form an oxide film as a p-type conductive film, particularly a p-type transparent conductive film without any subsequent heat treatment.

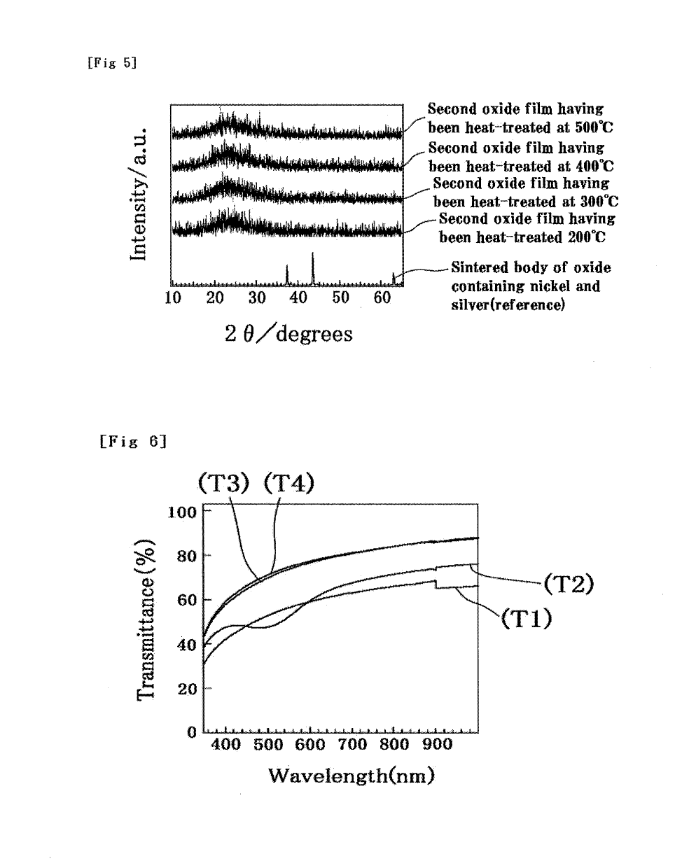

The inventors analyzed the crystal conditions of the second oxide film 12, which was obtained by heating the first oxide film 11 at a predetermined temperature (200° C., 300° C., 400° C., or 500° C.) by X-ray diffraction (XRD). FIG. 5 is a chart indicating X-ray diffraction (XRD) analysis results of the second oxide film in this embodiment. FIG. 5 also indicates XRD analysis results of a sintered body of an oxide containing silver (Ag) and nickel (Ni) as reference data. Found by this analysis was a broad halo peak considered to result from an amorphous form at 2θ in the range from 20° to 30° even in a case where the second oxide film was heated at any one of the temperatures as indicated in FIG. 5. In other words, no clear peak resulting from the sintered body of the oxide or the nickel oxide was observed.

In view of the XRD analysis results of no clear diffraction peak as described above, similarly to the first oxide film 11, the second oxide film 12 according to this embodiment is also considered to be an aggregate of microcrystals, an amorphous form including microcrystals, or an amorphous form. According to observation by the inventors using the scanning electron microscope, the second oxide film 12 is considered to have a very flat surface.

The inventors analyzed electrical properties and a conductance of the second oxide film 12 using the Hall effect measurement apparatus, similarly to the first oxide film 11. The second oxide film 12 heat-treated at 200° C. according to this embodiment had p-type conductivity and a conductance of about 4.3 S/cm. The second oxide film 12 heat-treated at 300° C. had p-type conductivity and a conductance of about 0.046 S/cm. The second oxide film 12 heat-treated at 400° C. had p-type conductivity and a conductance of about 6.3×10⁻⁴ S/cm. The second oxide film 12 heat-treated at 500° C. had p-type conductivity and a conductance of about 0.0032 S/cm.

The first oxide film and the second oxide film obtained by heating the first oxide film 11 at 200° C. or less were found to each have a conductance of 1 S/cm or more.

Interestingly, carrier mobility (hereinafter, also referred to simply as “mobility”) of the second oxide film 12 heat-treated at 200° C. was about 9.6 cm²/Vs and mobility of the second oxide film 12 heat-treated at 300° C. was increased to about 84 cm²/Vs. Mobility of the second oxide film 12 heat-treated at 400° C. or 500° C. was about 70 cm²/Vs to about 90 cm²/Vs.

Also from these results, the oxide film immediately after being deposited (i.e. the first oxide film) as well as the second oxide film obtained by heating the first oxide film at 200° C. or less were found to have high electrical properties. The inventors further found that the second oxide film 12 formed by heat-treating the first oxide film 11 in the atmosphere at 100° C. or more and 250° C. or less, particularly at 100° C. or more and 200° C. or less, can exhibit high mobility.

The inventors analyzed and found that the first oxide film 11 had a bandgap of about 3M eV. The second oxide film 12 formed by heat treatment at 200° C. had a bandgap of about 3.6 eV, and the second oxide film 12 formed by heat treatment at 400° C. also had a bandgap of about 3.6 eV. The second oxide film 12 formed by heat treatment at 500° C. also had a bandgap of about 3.6 eV. The first oxide film 11 and the second oxide film 12 according to this embodiment were thus found to each have a relatively broad bandgap of 3.0 eV or more and about 4.0 eV or less.

The inventors also calculated a transmittance of a light ray having a wavelength of 400 nm or more and 750 nm or less to the second oxide film 12, similarly to the measurement of the first oxide film 11.

FIG. 6 is a chart indicating transmittance analysis results of the second oxide film 12 in this embodiment. As indicated in FIG. 6, the transmittance of the second oxide film 12 to a light ray having a wavelength of 400 nm or more and 750 nm or less was found to depend on the heating temperature for the first oxide film 11. Specifically, the second oxide film 12 formed by heat treatment at 200° C. had a transmittance (T1 in FIG. 6) of about 57%, and the second oxide film 12 formed by heat treatment at 300° C. had a transmittance (T2 in FIG. 6) of about 57%. The second oxide film 12 formed by heat treatment at 400° C. had a transmittance (T3 in FIG. 6) of about 74%, and the second oxide film 12 formed by heat treatment at 500° C. had a transmittance (T4 in FIG. 6) of about 75%. The transmittance to a light ray having a wavelength of 400 nm or more and 750 nm or less was thus found to be at least 50% in any one of the above cases. Furthermore, the second oxide film particularly obtained by heating the first oxide film 11 at 400° C. or more and 500° C. or less was found to have a very high transmittance.

As described above, interestingly, the first oxide film 11 immediately after being deposited was found to have the excellent electrical properties, conductance, and transmittance through the analyses of the electrical properties, conductance, and transmittance. It is thus possible to form an oxide film as a p-type conductive film, particularly a p-type transparent conductive film without any subsequent heat treatment. The inventors further found that the second oxide film 12 obtained by heating in the atmosphere at 100° C. or more and 250° C. or less, particularly at 100° C. or more and 200° C. or less, can serve as a p-type conductive film or a p-type transparent conductive film more excellent in conductance and mobility.

Table 1 collectively indicates the respective analysis results. Table 1 does not include the expression of “about” for the sake of convenience. A carrier concentration was measured through Hall measurement by the van der Pauw's method.

TABLE 1

| | Film | Substrate temperature | Conduc- | Hall coef- | Carrier con- | | | |
|---|---|---|---|---|---|---|---|---|
| | thickness | during formation of | tance | ficient | centarion | Mobility | | Transmit- |
| Example | (nm) | first oxide film (° C.) | (S/cm) | (cm³/C) | (1/cm³) | (cm²/Vs) | Type | tance |
| Immediately after | 143 | 500 | 37 | 1.0 × 10⁻¹ | 6.1 × 10¹⁹ | 3.8 | P | 67% |
| being deposited | | | | | | | | |
| Second oxide film having | 140 | 500 | 4.3 | 2.3 | 2.8 × 10¹⁸ | 9.6 | P | 57% |
| been heat-treated at 200° C. | | | | | | | | |
| Second oxide film having | 143 | 500 | 0.016 | 1.8 × 10⁴ | 3.4 × 10¹⁴ | 840 | P | 74% |
| been heat-treated at 300° C. | | | | | | | | |
| Second oxide film having | 145 | 500 | 6.3 × 10⁻⁴ | 1.6 × 10⁵ | 4.2 × 10¹¹ | 87 | P | 74% |
| been heat-treated at 400° C. | | | | | | | | |
| Second oxide film having | 142 | 500 | 0.0032 | 2.2 × 10⁴ | 2.8 × 10¹⁴ | 72 | P | 74% |
| been heat-treated at 500° C. | | | | | | | | |

According to the analysis results described above as well as the measurement results of the carrier concentrations of the first oxide film 11 and the second oxide film 12, as indicated in Table 1, it was found that the carrier concentration has a tendency to increase as the first oxide film 11 was heated at a higher temperature. Further found was that the oxide film immediately after being deposited and the second oxide film 12 formed by heat treatment at 200° C. were found to each have high carrier mobility. Also from these results, the oxide film immediately after being deposited (i.e. the first oxide film) as well as the second oxide film obtained by heating the first oxide film at 200° C. or less were found to have very high electrical properties. Furthermore, the first oxide film without heat treatment interestingly achieves very high electrical properties and a very high conductance also in view of the carrier concentration and the mobility.

### Variation (1) of First Embodiment

A first oxide film 11 and a second oxide film 12 were formed under the same conditions for the pulse laser deposition apparatus 20 as those of the first embodiment except that the temperature of the stage 27 was 20° C. to 25° C. (the so called room temperature). Accordingly, the description duplicating with that of the first embodiment may not be provided repeatedly.

This embodiment can exhibit at least a part of the effects of the first oxide film 11 and the second oxide film 12 according to the first embodiment.

### Second Embodiment

A first oxide film 11 was formed under the same conditions for the pulse laser deposition apparatus 20 as those of the first embodiment except that the ratio of the number of the silver (Ag) atoms to the number of nickel (Ni) atoms assumed to be 1 is 0.02 in the constituent atoms of the target 30 as an oxide sintered body. Accordingly, the description duplicating with that of the first embodiment may not be provided repeatedly.

Analyzed in this embodiment by X-ray diffraction (XRD) were the crystal conditions of the first oxide film 11 in a case where the number of silver (Ag) atoms was 0.02 relatively to the number of nickel (Ni) atoms assumed to be 1 in the constituent atoms of the target 30, similarly to the first embodiment. FIG. 7 is a chart indicating X-ray diffraction (XRD) analysis results of the first oxide film 11 in this embodiment. The same test was repeated three times to check reproducibility as well in this embodiment. The first oxide films 11 thus obtained were denoted by a first oxide film A, a first oxide film B, and a first oxide film C for the sake of convenience. FIG. 7 also indicates XRD analysis results of a sintered body of an oxide containing silver (Ag) and nickel (Ni) and powdered nickel oxide as reference data.

As indicated in FIG. 7, a broad halo peak considered to result from an amorphous phase at 2θ in the range from 20° to 30° was found with fine reproducibility. Furthermore, a relatively weak peak, which is observed with the sintered body of the oxide containing silver (Ag) and nickel (Ni) or the powdered nickel oxide, was observed at around 37°.

Though different from the XRD analysis results of the first oxide film 11 according to the first embodiment, the first oxide film 11 according to this aspect is considered to be an aggregate of microcrystals, an amorphous form including microcrystals, or an amorphous form.

The transmittance to a light ray having a wavelength of 400 nm or more and 750 nm or less to each of the first oxide films 11 was calculated in this embodiment, similarly to the first embodiment.

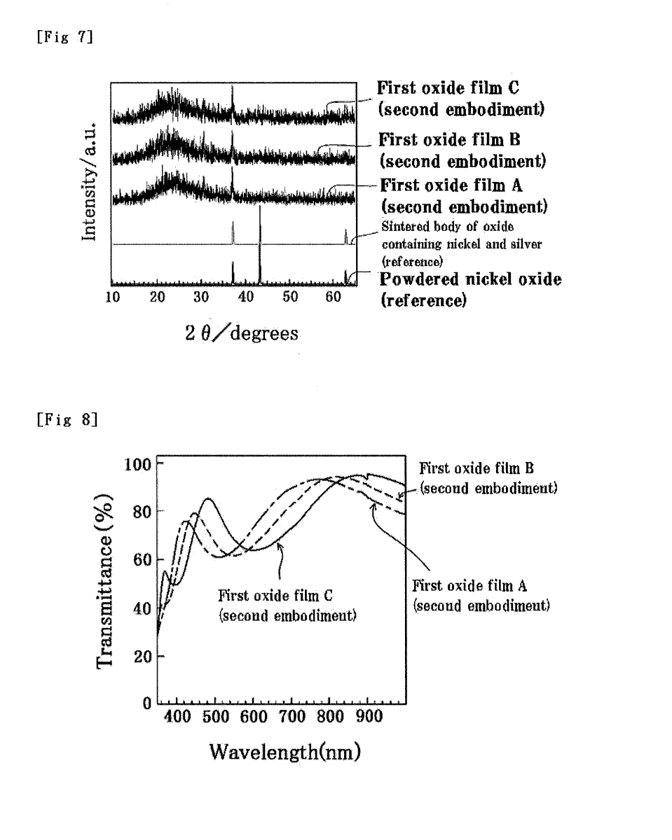

FIG. 8 is a chart indicating analysis results of the transmittance to a light ray having a wavelength principally in a visible light region, to each of the three first oxide films 11 (the first oxide films A, B, and C) according to this embodiment. The transmittance of the first oxide film A is indicated by a dashed line, whereas the transmittance of the first oxide film B is indicated by a broken line in the graph of FIG. 8. The transmittance of the first oxide film C is indicated by a solid line in the graph.

As indicated in FIG. 8, the transmittance of the first oxide film A was about 70% and the transmittance of the first oxide film B was about 72% in the first oxide films 11 according to this embodiment. The transmittance of the first oxide film C was as rather high as about 75%. The transmittance of each of the first oxide films 11 according to this embodiment was found to be at least 70%, more specifically, about 70% or more and about 75% or less.

The inventors analyzed electrical properties and conductances of the three first oxide films 11 according to this embodiment using the Hall effect measurement apparatus, similarly to the first embodiment. Table 2 collectively indicates the respective analysis results.

TABLE 2

| | Film | Substrate temperature | Conduc- | Hall coef- | Carrier con- | | | |
|---|---|---|---|---|---|---|---|---|
| | thickness | during formation of | tance | ficient | centration | Mobility | | Transmit- |
| Example | (nm) | first oxide film (° C.) | (S/cm) | (cm³/C) | (1/cm³) | (cm²/Vs) | Type | tance |
| First oxide film A | 170 | 500 | 28 | 0.031 | 2.0 × 10²⁰ | 0.87 | P | 70% |
| First oxide film B | 192 | 500 | 36 | 0.055 | 1.1 × 10²⁰ | 0.2 | P | 72% |
| First oxide film C | 208 | 500 | 13 | 0.052 | 1.2 × 10²⁵ | 0.7 | P | 75% |

As indicated in Table 2, The three first oxide films 11 according to this embodiment were found to have p-type conductivity and conductances as high as about 10 S/cm. Also found was that the mobility of each of the first oxide films 11 according to this embodiment was not as high as the mobility of the first oxide film 11 according to the first embodiment but its carrier concentration was higher than the carrier concentration of the first oxide film 11 according to the first embodiment.

As described above, the first oxide film 11 according to this embodiment was also found to have the excellent electrical properties, conductance, and transmittance through the analyses of the electrical properties, conductance, and transmittance.

### Third Embodiment

A first oxide film 11 was formed under the same conditions for the pulse laser deposition apparatus 20 as those of the first embodiment except that the ratio of the number of the silver (Ag) atoms to the number of nickel (Ni) atoms assumed to be 1 is 0.11 in the constituent atoms of the target 30 as an oxide sintered body. Accordingly, the description duplicating with that of the first embodiment may not be provided repeatedly.

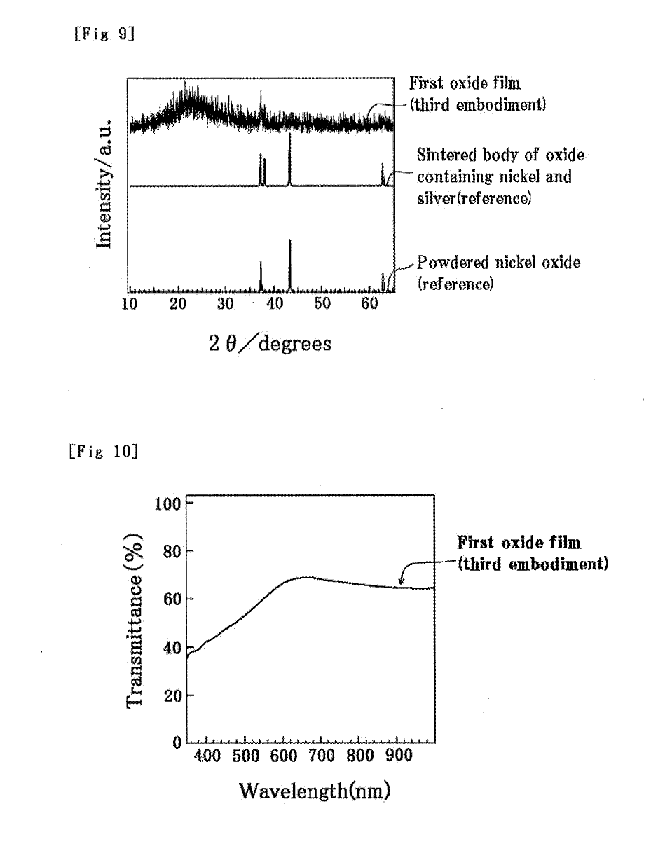

Analyzed in this embodiment by X-ray diffraction (XRD) were the crystal conditions of the first oxide film 11 in a case where the number of silver (Ag) atoms was 0.11 relatively to the number of nickel (Ni) atoms assumed to be 1 in the constituent atoms of the target 30, similarly to the first embodiment. FIG. 9 is a chart indicating X-ray diffraction (XRD) analysis results of the first oxide film 11 in this embodiment. FIG. 9 also indicates XRD analysis results of a sintered body of an oxide containing silver (Ag) and nickel (Ni) and powdered nickel oxide as reference data.

As indicated in FIG. 9, a broad halo peak was found, which was considered to result from an amorphous phase at 2θ in the range from 20° to 30°. Furthermore, similarly to the second embodiment, a relatively weak peak, which is observed with the sintered body of the oxide containing silver (Ag) and nickel (Ni) or the powdered nickel oxide, was observed at around 37°.

Though different from the XRD analysis results of the first oxide film 11 according to the first embodiment, the first oxide film 11 according to this aspect is considered to be an aggregate of microcrystals, an amorphous form including microcrystals, or an amorphous form.

The transmittance of a light ray having a wavelength of 400 nm or more and 750 nm or less to the first oxide film 11 according to this embodiment was calculated, similarly to the first embodiment.

FIG. 10 is a chart indicating analysis results of the transmittance to a light ray having a wavelength principally in a visible light region, to the first oxide film according to this embodiment. As indicated in FIG. 10, the transmittance of the first oxide film 11 according to this embodiment was about 59%. The transmittance of the first oxide film 11 according to this embodiment was thus found to be at least 50%.

The inventors analyzed electrical properties and conductances of the three first oxide films 11 according to this embodiment using the Hall effect measurement apparatus, similarly to the first embodiment. Table 3 collectively indicates the respective analysis results.

TABLE 3

| | Film | Substrate temperature | Conduc- | Hall coef- | Carrier con- | | | |
|---|---|---|---|---|---|---|---|---|
| | thickness | during formation of | tance | ficient | centration | Mobility | | Transmit- |
| Example | (nm) | first oxide film (° C.) | (S/cm) | (cm³/C) | (1/cm³) | (cm²/Vs) | Type | tance |
| First oxide film | 130 | 500 | 180 | 0.029 | 2.2 × 10²⁶ | 5.2 | P | 59% |
| (third embodiment) | | | | | | | | |

As indicated in Table 3, the first oxide film 11 according to this embodiment was found to have p-type conductivity and a conductance of 100 S/cm or more, more specifically, as extremely high as 180 S/cm. Its mobility was higher than the mobility of the first oxide film 11 according to the first embodiment. Its carrier concentration was found to be higher than the first oxide film 11 according to the first embodiment.

As described above, the first oxide film 11 according to this embodiment was also founded to have the excellent electrical properties, conductance, and transmittance through the analyses of the electrical properties, conductance, and transmittance.

### Other Embodiments

The first oxide film 11 is produced using the pulse laser deposition apparatus 20 in each of the embodiments described above, although the process for producing the first oxide film 11 is not limited thereto. For example, a physical vapor deposition method (PVD method) represented by an RF sputtering method or a magnetron sputtering method can be applied to these embodiment.

In the embodiments described above, an oxide sintered body is produced from an oxide as the target 30 for production of the first oxide film 11 or the second oxide film 12, but an oxide sintered body may be produced alternatively from a hydroxide (e.g., copper hydroxide), a nitrate (e.g., copper nitrate), a carbonate, or an oxalate.

As described above, variations within the scope of the present invention including other combinations of the embodiments are also included in claims.

### INDUSTRIAL APPLICABILITY

The present invention can be widely applied to an oxide film having p-type conductivity or a transparent conductive film having p-type conductivity.

1. An oxide film (possibly including inevitable impurities) containing silver (Ag) and nickel (Ni), wherein
the oxide film is an aggregate of an amorphous form including microcrystals, or an amorphous form, and has p-type conductivity.

2. The oxide film according to claim 1, wherein
the ratio of the number of the silver (Ag) atoms to the number of the nickel (Ni) atoms assumed to be 1 is 0.01 or more and 0.11 or less.

3. The oxide film according to claim 1, wherein
the oxide film is an aggregate of microcrystals or an amorphous form including microcrystals, and has a conductance of 1 S/cm or more.

4. The oxide film according to claim 1, wherein
the oxide film has a transmittance of 50% or more, of a light ray having a wavelength of 400 nm or more and 750 nm or less.

5. The oxide film according to claim 3, wherein
the oxide film has a bandgap of 3.0 eV or more and 4.0 eV or less.

6. A process for producing an oxide film, comprising the step of
scattering constituent atoms of a target of an oxide containing silver (Ag) and nickel (Ni) to form on a substrate a first oxide film (possibly including inevitable impurities) which is an aggregate of an amorphous form including microcrystals, or an amorphous form and has p-type conductivity.

7. The process for producing the oxide film according to claim 6, wherein
the ratio of the number of the silver (Ag) atoms to the number of the nickel (Ni) atoms assumed to be 1 is 0.01 or more and 0.11 or less.

8. The process for producing the oxide film according to claim 6, wherein
the substrate used for forming the first oxide film has a temperature of 0° C. or more and 500° C. or less, and gas used for forming the first oxide film has pressure of 0.01 Pa or more and 100 Pa or less.

9. The process for producing the oxide film according to claim 6, further comprising the step of
heating the first oxide film in an atmosphere at a temperature of 100° C. or more and 250° C. or less to form a second oxide film.

10. The process for producing the oxide film according to claim 6, wherein
the first oxide film is formed by scattering the constituent atoms of the target by a sputtering method or irradiation with a pulse laser ray.
